(19) United States
(12) Patent Application Publication
(10) Pub. No.: US 2016/0064585 A1
(43) Pub. Date: Mar. 3, 2016

(54) Adhesive for Solar Battery Protective Sheets

(71) Applicant: Henkel AG & Co. KGaA, Duesseldorf (DE)

(72) Inventors: Shoko Ito, Osaka (JP); Yasushi Yamada, Osaka (JP); Hitoshi Ikeda, Osaka (JP)

(21) Appl. No.: 14/937,927

(22) Filed: Nov. 11, 2015

Related U.S. Application Data
(63) Continuation of application No. PCT/JP2014/063141, filed on May 14, 2014.

(30) Foreign Application Priority Data
May 16, 2013 (JP) 2013-104257

(51) Int. Cl. H01L 31/049; C09J 133/14; C09J 133/10; H01L 31/048; C09J 133/08

(52) U.S. Cl. CPC H01L 31/049; H01L 31/0481; C09J 133/08; C09J 133/10; C09J 133/14

(57) ABSTRACT

The present invention provides an adhesive for solar battery protective sheets, comprising a urethane resin obtainable by mixing an acrylic polyol with an isocyanate compound; and a hydroxyphenyltriazine based compound, wherein the acrylic polyol is obtainable by polymerizing polymerizable monomers, the polymerizable monomers comprise a monomer having a hydroxyl group and other monomers, and the other monomers comprise acrylonitrile and (meth)acrylic ester(s). The adhesive for solar battery protective sheets has satisfactory initial adhesion to a film, satisfactory adhesion property to a film after aging, and excellent weatherability and hydrolysis resistance over the long term. The present invention also provides a solar battery protective sheet which is obtainable by using the adhesive.

### CROSS-REFERENCE TO RELATED APPLICATION

This application claims priority under Article 4 of the Paris Convention based on Japanese Patent Application No. 2013-104257 filed on May 16, 2013 in Japan, the entire content of which is incorporated herein by reference.

### TECHNICAL FIELD

The present invention relates to an adhesive for solar battery protective sheets. Moreover, the present invention relates to a solar battery protective sheet obtainable by using the adhesive, and a solar battery module obtainable by using the solar battery protective sheet.

### BACKGROUND ART

Practical use of a solar battery as useful energy resources makes progress. The solar battery includes various types, and a silicon-based solar battery, an inorganic compound-based solar battery, an organic solar battery and the like are known as a typical solar battery.

A surface (front surface) and a back surface of a solar battery module are protected with a sheet. Commonly, a sheet provided on a surface, on which sunlight falls, is a solar battery surface protective sheet, while a sheet provided on a surface opposite to the surface, on which sunlight falls, is a solar battery back surface protective sheet (back sheet). The back sheet is provided for the purpose of protecting a solar battery cell, and it is required for the back sheet to have various excellent physical properties such as weatherability, water resistance, heat resistance, moisture resistance and gas barrier properties so as to suppress long-term performance deterioration of the solar battery to the minimum extent.

In order to obtain a sheet having these various physical properties, various films are used. Examples of such film include metal foils, metal plates and metal deposited films, such as aluminum, copper and steel plates; plastic films such as polyethylene, polypropylene, polyvinyl chloride, polyester, fluorine resin, and acrylic resin films; and the like.

In order to further improve performances, a laminate of these films is also used as the protective sheet of the solar battery.

A solar battery back sheet obtained by laminating films is shown in FIG. 1, as an example of a solar battery protective sheet. A back sheet 10 is a laminate of plural films 11 and 12, and the films 11 and 12 are laminated by interposing an adhesive 13 therebetween.

A lamination method of films is commonly a dry lamination method. It is required for the adhesive 13 to have sufficient adhesive property to the films 11 and 12.

The back sheet 10 constitutes a solar battery module 1, together with a sealing material 20, a solar battery cell 30, and a glass plate 40 (see FIG. 3).

Since the solar battery module 1 is exposed outdoors over the long term, sufficient durability against high temperature, high humidity and sunlight is required. Particularly, when the adhesive 13 has low performances, the films 11 and 12 are peeled and thus the appearance of the laminated back sheet 10 is impaired. Therefore, it is required that the adhesive for solar battery back sheets does not undergo peeling of the film even when exposed over the long term.

Patent Documents 1 to 3 disclose that the use of films laminated by using a urethane-based adhesive enables production of a solar battery protective sheet which is less likely to cause peeling of films and is excellent in durability (see “Claims” and “Examples” of the respective documents). A urethane adhesive of Patent Documents 1 and 2 contains a triazine-based ultraviolet absorber, leading to an improvement in durability (see “claims” and “Examples” of the respective documents). Patent Document 3 discloses a urethane adhesive having excellent hydrolysis resistance and adhesion property which is obtainable by limiting a glass transition temperature of an acrylic polyol as a raw material within a specific range (see “claim 1” and “Examples” of Patent Document 3).

However, performances required for the adhesive for solar battery protective sheets increase year by year.

The solar battery protective sheet is commonly produced by applying an adhesive to a film, drying the adhesive, laminating the films (dry lamination method), and then aging (or curing) the obtained laminate at about 40 to 60° C. for several days. Therefore, it is important that the adhesive for solar battery protective sheets has sufficient initial adhesion to a film at the time of lamination and sufficient adhesive strength to a film after aging, and is also excellent in hydrolysis resistance.

A study has recently been made on the development of an organic solar battery having lower production costs than that of a solar battery using silicone or an inorganic compound material. The organic solar battery is characterized as being capable of undergoing coloration and also having flexibility. Therefore, a transparent film tends to be used as a film constituting a solar battery protective sheet. Accordingly, it is also required for the adhesive for solar battery protective sheets to maintain adhesive strength over the long term, and also to cause small color difference leading to extremely excellent weatherability even when exposed to ultraviolet rays over the long term.

Although the adhesives of Documents 1 to 3 include a triazine-based ultraviolet absorber and are excellent in weatherability (see “claims” of the respective Documents), it is unclear whether or not they sufficiently satisfy high-level weatherability required for an organic solar battery.

Patent Document 1: JP 2011-181732 A

Patent Document 2: JP 2012-116880 A

Patent Document 3: JP 2012-142349 A

### DISCLOSURE OF THE INVENTION

### Problems to be Solved by the Invention

The present invention has been made so as to solve such a problem and an object thereof is to provide an adhesive for solar battery protective sheets, which has satisfactory initial adhesion to a film at the time of the production of a solar battery protective sheet, satisfactory adhesive strength (adhesion property) to a film after aging, and also has excellent long-term weatherability and hydrolysis resistance; a solar battery protective sheet obtainable by using the adhesive; and a solar battery module obtainable by using the solar battery protective sheet.

### Means for Solving the Problems

The present inventors have intensively studied and found, surprisingly, that it is possible to obtain an adhesive for solar battery protective sheets, which has improved initial adhesion to a film and improved initial adhesion property after aging, and is also excellent in long-term weatherability and hydrolysis resistance, and overall balance, by using a specific acrylic polyol and a specific ultraviolet absorber as raw materials of a urethane resin, and thus the present invention has been completed.

Namely, the present invention provides, in an aspect, an adhesive for solar battery protective sheets, comprising a urethane resin obtainable by mixing an acrylic polyol with an isocyanate compound; and a hydroxyphenyltriazine based compound,

wherein the acrylic polyol is obtainable by polymerizing polymerizable monomers,

the polymerizable monomers comprise a monomer having a hydroxyl group and other monomers, and

the other monomers comprise acrylonitrile and (meth)acrylic ester(s).

The present invention provides, in an embodiment, the above adhesive for solar battery protective sheets, wherein the acrylic polyol has a glass transition temperature of −40° C. to 20° C.

The present invention provides, in an embodiment, the above adhesive for solar battery protective sheets, wherein the isocyanate compound comprises at least one selected from xylylene diisocyanate and hexamethylene diisocyanate derivatives.

The present invention provides, in an embodiment, the above adhesive for solar battery protective sheets, wherein the content of the acrylonitrile is 1 to 40 parts by weight based on 100 parts by weight of the polymerizable monomers.

The present invention provides, in another aspect, a solar battery protective sheet obtainable by using any one of the above adhesives for solar battery protective sheets

The present invention provides, in a preferred aspect, a solar battery module obtainable by using the above solar battery protective sheet.

The present invention provides, in still another aspect, a raw material comprising an acrylic polyol for producing any one of the adhesives for solar battery protective sheets,

wherein the acrylic polyol is obtainable by polymerizing polymerizable monomers,

the polymerizable monomers comprise a monomer having a hydroxyl group and other monomers, and

the other monomers comprise acrylonitrile and (meth)acrylic ester(s).

### Effects of the Invention

The adhesive for solar battery protective sheets of the present invention maintains excellent hydrolysis resistance and has sufficient initial adhesion to a film, and also has excellent adhesion property after aging, and excellent long-term weatherability and hydrolysis resistance. Blending of acrylonitrile and a hydroxyphenyltriazine-based compound enables significant improvement in adhesion property and weatherability of the adhesive for solar battery protective sheets. Therefore, the adhesive for solar battery protective sheets of the present invention is particularly preferable for an organic solar battery application which requires high-level durability.

Since the solar battery protective sheet of the present invention is producible by using the above adhesive, even when exposed to a high temperature/high humidity state under UV environment, neither peeling of a laminated film nor a large change in color difference of a film occurs, and thus the appearance can be maintained over the long term. Because of high weatherability of the adhesive, the solar battery protective sheet of the present invention is particularly useful as a protective sheet of an organic solar battery using a transparent film.

Since the solar battery module of the present invention is producible by using the above sheet, peeling of a laminated film does not occur, and thus the appearance is maintained. Because of excellent weatherability and hydrolysis resistance of the adhesive for solar battery protective sheets, the solar battery of the present invention is excellent in electrical characteristics (dielectric strength, etc.).

### BRIEF DESCRIPTION OF DRAWINGS

FIG. 1 is a sectional view showing an embodiment (back sheet) of a solar battery protective sheet of the present invention.

FIG. 2 is a sectional view showing another embodiment (back sheet) of a solar battery protective sheet of the present invention.

FIG. 3 is a sectional view showing an embodiment of a solar battery module of the present invention.

### DESCRIPTION OF EMBODIMENTS

The adhesive for solar battery protective sheets according to the present invention comprises (A) a urethane resin obtainable by the reaction of (a1) an acrylic polyol with (a2) an isocyanate compound, and (B) a hydroxyphenyltriazine-based compound.

The urethane resin (A) according to the present invention is a polymer obtainable by the reaction of (a1) an acrylic polyol with (a2) an isocyanate compound, and has a urethane bond. A hydroxyl group of the acrylic polyol reacts with an isocyanate group.

The acrylic polyol (a1) is obtainable by the addition polymerization of polymerizable monomers, and the polymerizable monomers comprise a “monomer having a hydroxyl group” and “other monomers”.

The “monomer having a hydroxyl group” includes hydroxyalkyl (meth)acrylate, and the hydroxyalkyl (meth)acrylate may be used alone or two or more kinds of the hydroxyalkyl (meth)acrylates may be used in combination. The hydroxyalkyl (meth)acrylate may also be used in combination with a monomer having a hydroxyl group, other than the hydroxyalkyl (meth)acrylate.

Examples of the “hydroxyalkyl (meth)acrylate” include, but are not limited to, 2-hydroxyethyl (meth)acrylate, 2-hydroxypropyl (meth)acrylate, 3-hydroxypropyl (meth)acrylate, 4-hydroxybutyl acrylate and the like.

Examples of the “polymerizable monomer having a hydroxyl group, other than the hydroxylalkyl (meth)acrylate” include polyethylene glycol mono(meth)acrylate, polypropylene glycol mono(meth)acrylate and the like.

The “other monomers” are “radical polymerizable monomers having an ethylenic double bond” other than the monomer having a hydroxyl group. The other monomers include acrylonitrile and a (meth)acrylic acid ester. The other monomers may include only acrylonitrile and (meth)acrylic ester, or may further include radical polymerizable monomers having an ethylenic double bond, other than acrylonitrile and a (meth)acrylic ester.

The “(meth)acrylic ester” is a compound obtainable by the condensation reaction of (meth)acrylic acid with a monoalcohol, and has an ester bond. Specific examples thereof include methyl (meth)acrylate, ethyl (meth)acrylate, butyl (meth)acrylate, cyclohexyl (meth)acrylate, 2-ethylhexyl (meth)acrylate, dicyclopentanyl (meth)acrylate, glycidyl (meth)acrylate, isobornyl (meth)acrylate and the like. In the present invention, it is preferred to include at least one selected from methyl (meth)acrylate, ethyl (meth)acrylate, butyl (meth)acrylate, cyclohexyl (meth)acrylate and 2-ethylhexyl (meth)acrylate, and it is more preferred to include at least one selected from methyl (meth)acrylate and butyl (meth)acrylate. It is particularly preferred to include both butyl acrylate and methyl methacrylate.

The content of the (meth)acrylic acid ester in the polymerizable monomers is preferably 50 to 95 parts by weight, more preferably 60 to 95 parts by weight, and particularly preferably 70 to 90 parts by weight, based on 100 parts by weight of the polymerizable monomers. When the content of the (meth)acrylic acid ester is 50 to 95 parts by weight, it is possible to obtain an adhesive for solar battery protective sheets, which is more excellent in initial adhesion, weatherability and hydrolysis resistance.

Examples of the “radical polymerizable monomers having an ethylenic double bond, other than acrylonitrile and a (meth)acrylic acid ester” include, but are not limited to, (meth)acrylic acid, styrene, vinyltoluene and the like.

The “acrylonitrile” is a compound represented by the general formula: CH₂═CH—CN, and is also called acrylic nitrile, acrylic acid nitrile or vinyl cyanide.

The content of the acrylonitrile in the polymerizable monomers is preferably 1 to 40 parts by weight, more preferably 5 to 35 parts by weight, and particularly preferably 5 to 25 parts by weight, based on 100 parts by weight of the polymerizable monomers. When the content of the acrylonitrile is 1 to 40 parts by weight, it is possible to obtain an adhesive for solar battery protective sheets, which is excellent in balance among coatability, initial adhesion to a film after aging, and weatherability.

In the present description, an acrylic acid and a methacrylic acid are collectively referred to as a “(meth)acrylic acid”, and “an acrylic ester and a methacrylic ester” are collectively referred to as a “(meth)acrylic ester” or a “(meth)acrylate”.

As long as the objective adhesive for solar battery protective sheets of the present invention can be obtained, there is no particular limitation on the polymerization method of the polymerizable monomers. It is possible to exemplify, as the polymerization method, for example, a conventional solution polymerization method, and the above-mentioned polymerizable monomers can be radical-polymerized by appropriately using a catalyst in an organic solvent. Herein, the “organic solvent” can be used so as to polymerize the polymerizable monomers and there is no particular limitation on the organic solvent as long as it does not substantially exert an adverse influence on characteristics as an adhesive for solar battery protective sheets after the polymerization reaction. Examples of such a solvent include aromatic-based solvents such as toluene and xylene; ester-based solvents such as ethyl acetate and butyl acetate; and combinations thereof.

The polymerization reaction conditions such as reaction temperature, reaction time, kind of organic solvents, kind and concentration of monomers, stirring rate, as well as kind and concentration of catalysts in the polymerization of the polymerizable monomers can be appropriately selected according to characteristics of the objective adhesive.

The “initiator” is preferably a compound which can accelerate the polymerization of the polymerizable monomers by the addition in a small amount and can be used in an organic solvent. Examples of the catalyst include ammonium persulfate, sodium persulfate, potassium persulfate, t-butyl peroxybenzoate, 2,2-azobisisobutyronitrile (AIBN), 2,2-azobis(2-aminodipropane) dihydrochloride and 2,2-azobis(2,4-dimethylvaleronitrile), and 2,2-azobisisobutyronitrile (AlBN) is particularly preferable.

A chain transfer agent can be appropriately used for the polymerization in the present invention so as to adjust the molecular weight. It is possible to use, as the “chain transfer agent”, compounds well-known to those skilled in the art. Examples thereof include mercaptans such as n-dodecylmercaptan (nDM), laurylmethylmercaptan and mercaptoethanol.

As mentioned above, the acrylic polyol is obtainable by polymerizing the polymerizable monomers. From the viewpoint of coatability of the adhesive, the weight average molecular weight (Mw) of the acrylic polyol is preferably 200,000 or less, and more preferably 5,000 to 100,000. The weight average molecular weight is a value in which the value measured by gel permeation chromatography (GPC) is expressed in terms of a polystyrene standard. Specifically, Mw can be measured using the following GPC apparatus and measuring method. HCL-8220GPC manufactured by TOSOH CORPORATION is used as a GPC apparatus, and RI is used as a detector. Two TSK gel SuperMultipore HZ-M manufactured by TOSOH CORPORATION are used as a GPC column. A sample is dissolved in tetrahydrofuran and the obtained solution is allowed to flow at a flow rate of 0.35 ml/min and a column temperature of 40° C. to obtain a value (measured), and then Mw is determined by conversion of molecular weight (the value measured) based on a calibration curve which is obtained by using polystyrene having a monodisperse molecular weight as a standard reference material.

A glass transition temperature of the acrylic polyol can be set by adjusting a mass fraction of a monomer to be used. The glass transition temperature of the acrylic polyol can be determined based on a glass transition temperature of a homopolymer obtainable from each monomer and a mass fraction of the homopolymer used in the acrylic polyol using the following calculation formula (i). It is preferred to determine a composition of the monomer using the glass transition temperature determined by the calculation:

1/Tg=W1/Tg1+W2/Tg2+ . . . +Wn/Tgn (i):

where in the above formula (i), Tg denotes the glass transition temperature of the acrylic polyol, each of W1, W2, . . . , Wn denotes a mass fraction of each monomer, and each of Tg1, Tg2, . . . , and Tgn denotes a glass transition temperature of a homopolymer of corresponding each monomer.

A value disclosed in documents can be used as Tg of the homopolymer. It is possible to refer, as such a document, for example, the following documents: Acrylic Ester Catalog of Mitsubishi Rayon Co., Ltd. (1997 Version); edited by Kyozo Kitaoka, “Shin Kobunshi Bunko 7, Guide to Synthetic Resin for Coating Material”, Kobunshi Kankokai, published in 1997, pp. 168-169; and “POLYMER HANDBOOK”, 3rd Edition, pp. 209-277, John Wiley & Sons, Inc. published in 1989.

In the present description, glass transition temperatures of homopolymers of the following monomers are as follows.

### Styrene: 105° C.

Methyl methacrylate: 105° C.
n-Butyl acrylate: −54° C.
Ethyl acrylate: −20° C.
2-Ethylhexyl acrylate: −70° C.
Cyclohexyl methacrylate: 83° C.
Glycidyl methacrylate: 41° C.

### Acrylonitrile: 130° C.

2-Hydroxyethyl methacrylate: 55° C.
2-Hydroxyethyl acrylate: −15° C.
2-(2′-Hydroxy-5′-methacryloyloxyethylphenyl)-2H-benzotriazole (manufactured by Otsuka Chemical Co., Ltd.): 60° C.

In the present invention, the glass transition temperature of the acrylic polyol is preferably −40 to 20° C., more preferably −35° C. to 10° C., and particularly preferably −30° C. to 0° C., from the viewpoint of initial adhesion to a film at the time of lamination.

When the glass transition temperature of the acrylic polyol is −40 to 20° C., the adhesive for solar battery protective sheets is more excellent in initial adhesion to a film and adhesion property after aging.

A hydroxyl value of the acrylic polyol is preferably 0.5 to 45 mgKOH/g, more preferably 1 to 40 mgKOH/g, and particularly preferably 5 to 35 mgKOH/g. When the hydroxyl value of the acrylic polyol is 0.5 to 45 mgKOH/g, it is possible to obtain an adhesive for solar battery protective sheets, which is more excellent in initial adhesion to a film, adhesion property after aging, and hydrolysis resistance.

In the present description, the hydroxyl value is a number of mg of potassium hydroxide required to neutralize acetic acid combined with hydroxyl groups when 1 g of a resin is acetylated.

In the present invention, the hydroxyl value is specifically calculated by the following formula (ii).

(ii): Hydroxyl value=[(weight of (meth)acrylate having a hydroxyl group)/(molecular weight of (meth)acrylate having a hydroxyl group)]×(mole number of hydroxyl groups contained in 1 mol of (meth)acrylate monomer having a hydroxyl group)×[(formula weight of KOH×1,000)/(weight of the acrylic polyol)]

In the present invention, the isocyanate compound (a2) is usually a compound used to produce a polyurethane resin and is not particularly limited as long as the objective adhesive for solar battery protective sheets of the present invention can be obtained, and includes an isocyanate monomer and an isocyanate derivative.

Examples of the isocyanate derivative include a trimethylolpropane adduct, an isocyanurate form, a biuret form, an allophanate form, and a block isocyanate.

Examples of the isocyanate compound (a2) according to the present invention include an aliphatic isocyanate, an alicyclic isocyanate, and an aromatic isocyanate.

In the present specification, the “aliphatic isocyanate” refers to a compound which has a chain-like hydrocarbon chain in which isocyanate groups are directly combined to the hydrocarbon chain, and also has no cyclic hydrocarbon chain. Although the “aliphatic isocyanate” may have an aromatic ring, the aromatic ring is not directly combined with the isocyanate groups.

In the present description, the aromatic ring is not included in the cyclic hydrocarbon chain.

The “alicyclic isocyanate” is a compound which has a cyclic hydrocarbon chain and may have a chain-like hydrocarbon chain. The isocyanate group may be either directly combined with the cyclic hydrocarbon chain, or may be directly combined with the chain-like hydrocarbon chain which may be present. Although the “alicyclic isocyanate” may include an aromatic ring, the aromatic ring is not directly combined to the isocyanate groups.

The “aromatic isocyanate” refers to a compound which has an aromatic ring, in which isocyanate groups are directly combined with the aromatic ring. Therefore, a compound, in which isocyanate groups are not directly combined with the aromatic ring, is classified into the aliphatic isocyanate or the alicyclic isocyanate even if it includes the aromatic ring in the molecule.

Therefore, for example, 4,4′-diphenylmethane diisocyanate (OCN—C₆H₄—CH₂—C₆H₄—NCO) corresponds to the aromatic isocyanate, since the isocyanate groups are directly combined with the aromatic ring. On the other hand, for example, xylylene diisocyanate (OCN—CH₂—C₆H₄—CH₂—NCO) corresponds to the aliphatic isocyanate since it includes an aromatic ring, but the isocyanate groups are not directly combined with the aromatic ring and combined with methylene groups.

The aromatic ring may be a ring in which two or more benzene rings are fused.

Examples of the aliphatic isocyanate include 1,4-diisocyanatobutane, 1,5-diisocyanatopentane, 1,6-diisocyanatohexane (hereinafter referred to as (hexamethylene diisocyanate (HDI)), 1,6-diisocyanato-2,2,4-trimethylhexane, 2,6-diisocyanatohexanoic acid methyl ester (lysine diisocyanate), 1,3-bis(isocyanatomethyl)benzene (xylylene diisocyanate (XDI)) and the like.

Examples of the alicyclic isocyanate include 5-isocyanato-1-isocyanatomethyl-1,3,3-trimethylcyclohexane (isophorone diisocyanate (IPDI)), 1,3-bis(isocyanatomethyl)cyclohexane (hydrogenated xylylene diisocyanate), bis(4-isocyanatocyclohexyl)methane (hydrogenated diphenylmethane diisocyanate), 1,4-diisocyanatocyclohexane and the like.

Examples of the aromatic isocyanate include, 4,4′-diphenylmethane diisocyanate, p-phenylene diisocyanate, m-phenylene diisocyanate and the like. These isocyanate compounds can be used alone, or in combination.

In the present invention, there is no particular limitation on the isocyanate compound (a2) as long as the objective adhesive for solar battery protective sheets according to the present invention can be obtained. From the viewpoint of weatherability, it is preferred to include the aliphatic isocyanate. It is more preferred to include at least one selected from xylylene diisocyanate and hexamethylene diisocyanate derivatives, and it is most preferred to include a hexamethylene diisocyanate trimer. It is more preferred that the isocyanate compound (a2) includes at least one selected from xylylene diisocyanate and hexamethylene diisocyanate derivatives, since long-term weatherability and adhesion property to a film after aging of the adhesive for solar battery protective sheets are more improved.

The urethane resin (A) according to the present invention can be obtained by reacting the acrylic polyol (a1) with the isocyanate compound (a2). In the reaction, a known method can be used and the reaction can be usually performed by mixing the acrylic polyol (a1) with the isocyanate compound (a2). There is no particular limitation on the mixing method as long as the urethane resin (A) according to the present invention can be obtained.

In the present description, the “hydroxyphenyltriazine-based compound (B)” is a kind of a triazine derivative in which a hydroxyphenyl derivative is combined with a carbon atom of the triazine derivative, which is commonly referred to as a hydroxyphenyltriazine-based compound, and there is no particular limitation as long as the objective adhesive for solar battery protective sheets of the present invention can be obtained.

Examples of such hydroxyphenyltriazine-based compound include compounds represented by the following chemical formulas (1) to (5) and isomers thereof, and these compounds are preferable, but the hydroxyphenyltriazine-based compound is not limited thereto.

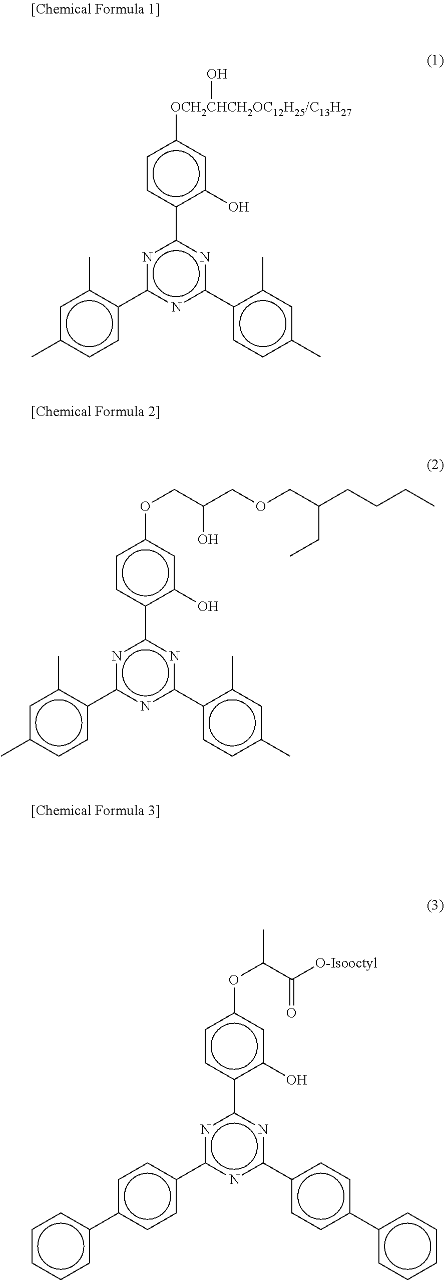

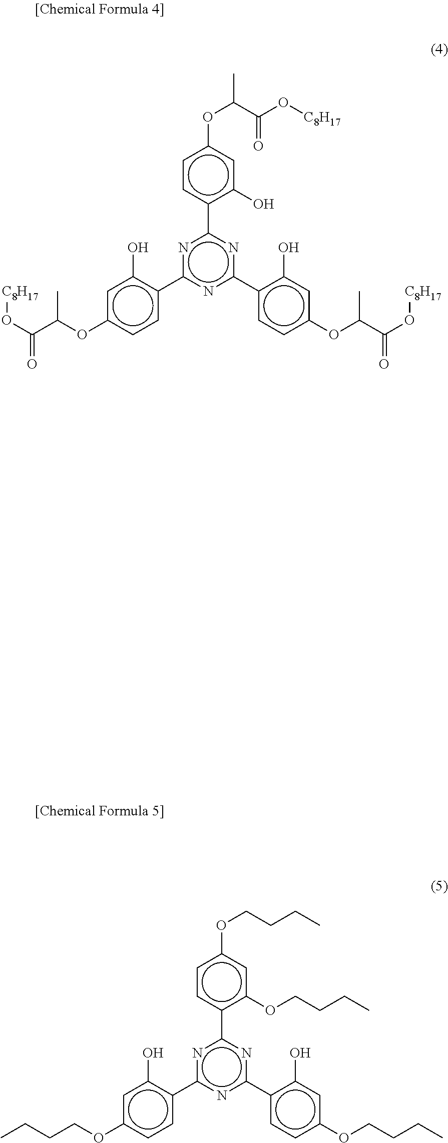

The hydroxyphenyltriazine-based compounds (B) of the chemical formulas (1) to (5) are commonly used as an ultraviolet absorber and can be used in combination with other ultraviolet absorbers as long as the objective adhesive for solar battery protective sheets of the present invention can be obtained. It is possible to use, as the hydroxyphenyltriazine-based compound, commercially available products. For example, they are commercially available from BASF Corp under the trade names of TINUVIN 400, TINUVIN 405, TINUVIN 479, TINUVIN 477, TINUVIN 460 and the like.

The adhesive for solar battery protective sheets of the present invention may further contain, in addition to the urethane resin and the hydroxyphenyltriazine-based compound, a silane compound.

In the present invention, it is possible to use, as the silane compound, for example, (meth)acryloxyalkyltrialkoxysilanes, (meth)acryloxyalkylalkylalkoxysilanes, vinyltrialkoxysilanes, vinylalkylalkoxysilanes, epoxysilanes, mercaptosilanes, and isocyanuratesilanes. The silane compound is not limited only to these silane compounds.

Examples of the “(meth)acryloxyalkyltrialkoxysilanes” include 3-(meth)acryloxypropyltrimethoxysilane, 3-(meth)acryloxypropyltriethoxysilane, 4-(meth) acryloxyethyltrimethoxysilane and the like.

Examples of the “(meth)acryloxyalkylalkylalkoxysilanes” include 3-(meth)acryloxypropylmethyldimethoxysilane, 3-(meth)acryloxypropylmethyldiethoxysilane, 3-(meth)acryloxypropylethyldiethoxysilane, 3-(meth)acryloxyethylmethyldimethoxysilane and the like.

Examples of the “vinyltrialkoxysilanes” include vinyltrimethoxysilane, vinyltriethoxysilane, vinyldimethoxyethoxysilane, vinyltri(methoxyethoxy)silane, vinyltri(ethoxymethoxy)silane and the like.

Examples of the “vinylalkylalkoxysilanes” include vinylmethyldimethoxysilane, vinylethyldi(methoxyethoxy)silane, vinyldimethylmethoxysilane, vinyldiethyl(methoxyethoxy)silane and the like.

For example, the “epoxysilanes” can be classified into glycidyl-based silanes and epoxycyclohexyl-based silanes. The “glycidyl-based silanes” have a glycidoxy group, and specific examples thereof include 3-glycidoxypropylmethyldiisopropenoxysilane, 3-glycidoxypropyltrimethoxysilane, 3-glycidoxypropyltriethoxysilane, 3-glycidoxypropyldiethoxysilane and the like.

The “epoxycyclohexyl-based silane” has a 3,4-epoxycyclohexyl group, and specific examples thereof include 2-(3,4 epoxycyclohexyl)ethyltrimethoxysilane, 2-(3,4 epoxycyclohexyl)ethyltriethoxysilane and the like.

Examples of the “mercaptosilanes” include 3-mercaptopropyltrimethoxysilane, 3-mercaptopropyltriethoxysilane and the like.

Examples of the “isocyanuratesilanes” include tris(3-(trimethoxysilyl)propyl)isocyanurate and the like.

These silane compounds enable, in addition to an improvement in peel strength, an improvement in weatherability of an adhesive containing a hydroxyphenyltriazine-based compound. In the present invention, it is particularly preferred to add epoxysilanes since performances of the adhesive for solar battery protective sheets are significantly improved.

It is preferred that the adhesive for solar battery protective sheets of the present invention further contains at least one selected from a hindered phenol-based compound and a hindered amine-based compound.

The “hindered phenol-based compound” is commonly referred to as a hindered phenol-based compound and is not particularly limited as long as the objective adhesive for solar battery protective sheets of the present invention can be obtained.

Commercially available products can be used as the hindered phenol-based compound. It is possible to use, as the hindered phenol-based compound, for example, products under the trade names of IRGANOX1010, IRGANOX1035, IRGANOX1076, IRGANOX1135, IRGANOX1330 and IRGANOX1520 and the like. The hindered phenol-based compound is added to the adhesive as an antioxidant and may be used, for example, in combination with a phosphite-based antioxidant, a thioether-based antioxidant, an amine-based antioxidant and the like.

The “hindered amine-based compound” is commonly referred to as a hindered amine-based compound, and there is no particular limitation as long as the objective adhesive for solar battery protective sheets according to the present invention can be obtained.

Commercially available products can be used as the hindered amine-based compound. It is possible to use, as the hindered amine-based compound, for example, TINUVIN 765, TINUVIN 111FDL, TINUVIN 123, TINUVIN 144, TINUVIN 152, TINUVIN 292, TINUVIN 5100 and the like. The hindered amine-based compound is added to the adhesive as a light stabilizer and may be used, for example, in combination with a benzotriazole-based light stabilizer, a benzoate-based light stabilizer and the like.

The adhesive for solar battery protective sheets according to the present invention can further contain “other component(s)”. There is no particular limitation on timing of the addition of the other component(s) to the adhesive for solar battery protective sheets. For example, the other component(s) may be added, together with the isocyanate compound and the acrylic polyol, in the synthesis of the urethane resin, or may be added together when the hydroxyphenyltriazine-based compound is added after synthesizing the urethane resin by reacting the acrylic polyol with the isocyanate compound.

Examples of the “other component(s)” include a tackifier resin, a dye, a plasticizer, a flame retardant, a catalyst, a wax and the like.

Examples of the “tackifier resin” include a styrene-based resin, a terpene-based resin, aliphatic petroleum resin, an aromatic petroleum resin, a rosin ester, an acrylic resin, a polyester resin (excluding polyester polyol) and the like.

Examples of the “dye” include titanium oxide, carbon black and the like.

Examples of the “plasticizer” include dioctyl phthalate, dibutyl phthalate, diisononyl adipate, dioctyl adipate, mineral spirit and the like.

Examples of the “flame retardant” include a halogen-based flame retardant, a phosphorous-based flame retardant, an antimony-based flame retardant, a metal hydroxide-based flame retardant and the like.

Examples of the “catalyst” include metal catalysts such as tin catalysts (trimethyltin laurate, trimethyltin hydroxide, dibutyltin dilaurate, dibutyltin maleate, etc.), lead-based catalysts (lead oleate, lead naphthenate, lead octenoate, etc.), and other metal catalysts (naphthenic acid metal salts such as cobalt naphthenate) and amine-based catalysts such as triethylenediamine, tetramethylethylenediamine, tetramethylhexylenediamine, diazabicycloalkenes, dialkylaminoalkylamines and the like.

The “wax” is preferably wax such as a paraffin wax and a microcrystalline wax.

The adhesive for solar battery protective sheets of the present invention can be produced by mixing the above-mentioned urethane resin and hydroxyphenyltriazine-based compound, and the other component(s) optionally added, for example, a silane compound, a hindered phenol-based compound, a hindered amine-based compound, and other component(s). There is no particular limitation on the mixing method as long as the objective adhesive for solar battery protective sheets of the present invention can be obtained. There is also no particular limitation on the order of mixing the components. The adhesive for solar battery protective sheets according to the present invention can be produced without requiring a special mixing method and a special mixing order. The obtained adhesive for solar battery protective sheets is excellent in adhesive strength, hydrolysis resistance, and weatherability.

It is required for an adhesive for producing a solar battery module to have strength and weatherability in particularly high level. The adhesive for solar battery protective sheets of the present invention is excellent in adhesion property after aging (peel strength), hydrolysis resistance, and weatherability, and thus the adhesive is suitable as an adhesive for solar battery protective sheets and is particularly suitable as an adhesive for organic solar battery back sheets.

In the case of producing a solar battery protective sheet, the adhesive for solar battery protective sheets of the present invention is applied to a film. The application can be performed by various methods, for example, gravure coating, wire bar coating, air knife coating, die coating, lip coating and comma coating methods. Plural films coated with the adhesive for solar battery protective sheets of the present invention are laminated with each other, thus completing a solar battery protective sheet.

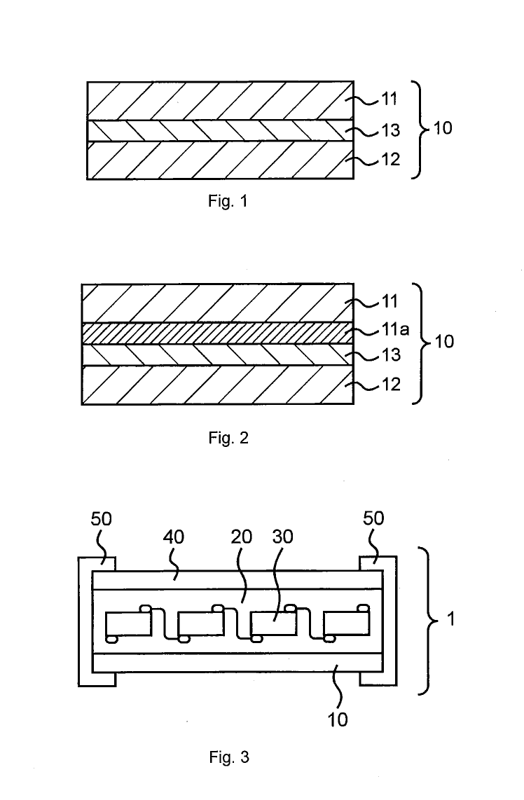

Embodiments of the solar battery protective sheet of the present invention are shown in FIGS. 1 to 3, but the present invention is not limited to these embodiments.

FIG. 1 is a sectional view of a solar battery back sheet as an embodiment of a solar battery protective sheet of the present invention. The solar battery protective sheet 10 is formed of two films and an adhesive for solar battery protective sheets 13 interposed therebetween, and the two films 11 and 12 are laminated to each other by the adhesive for solar battery protective sheets 13. The films 11 and 12 may be made of either the same or different material. In FIG. 1, the two films 11 and 12 are laminated to each other, or three or more films may be laminated to one another.

Another embodiment of the solar battery protective sheets according to the present invention is shown in FIG. 2. In FIG. 2, a thin film 11a is formed between the film 11 and the adhesive for solar battery protective sheets 13. For example, the drawing shows an embodiment in which a metal thin film 11a is formed on the surface of the film 11 when the film 11 is a plastic film. The metal thin film 11a can be formed on the surface of the plastic film 11 by vapor deposition, and the solar battery protective sheet of FIG. 2 can be obtained by laminating the metal thin film 11, on which surface the metal thin film 11a is formed, with the film 12 by interposing the adhesive for solar battery protective sheets 13 therebetween.

Examples of the metal to be deposited on the plastic film include aluminum, steel, copper and the like. It is possible to impart barrier properties to the plastic film by subjecting the film to vapor deposition. Silicon oxide or aluminum oxide is used as a vapor deposition material. The plastic film 11 as a base material may be either transparent, or white- or black-colored.

A plastic film made of polyvinyl chloride, polyester, a fluorine resin or an acrylic resin is used as the film 12. In order to impart heat resistance, weatherability, rigidity, insulating properties and the like, a polyethylene terephthalate film or a polybutylene terephthalate film is particularly preferably used. The films 11 and 12 may be either transparent, or may be colored.

The deposited thin film 11a of the film 11 and the film 12 are laminated to each other using the adhesive for solar battery protective sheets 13 according to the present invention, and the films 11 and 12 are often laminated to each other by dry lamination method.

FIG. 3 shows a sectional view of an example of a solar battery module of the present invention. In FIG. 3, it is possible to obtain a solar battery module 1 by laying a glass plate 40, a sealing material 20 such as an ethylene-vinyl acetate resin (EVA), plural solar battery cells 30 which are commonly connected to each other to generate a desired voltage, and a back sheet 10 on one another, and then fixing these members 10, 20, 30 and 40 using a spacer 50.

As mentioned above, since the back sheet 10 is a laminate of the plural films 11 and 12, it is required for the adhesive for solar battery protective sheets 13 to cause no peeling of the films 11 and 12 even when the back sheet 10 is exposed outdoors over the long term.

The solar battery cell 30 is often producible by using silicon, and is also sometimes produced by using an organic resin containing a dye. In that case, the solar battery module 1 becomes an organic (dye-sensitized) solar battery module. Since it is required for the organic (dye-sensitized) solar battery to have colorability, a transparent film is often used as the films 11 and 12 which constitute the solar battery back sheet 10. Therefore, it is required for the adhesive for solar battery protective sheets 13 to cause small color difference leading to excellent weatherability even when exposed outdoors over the long term.

As mentioned above, the adhesive for solar battery protective sheets of the present invention is not only excellent in hydrolysis resistance, but also causes a small color difference. Therefore, the adhesive for solar battery protective sheets of the present invention is significantly useful for the production of a protective sheet of an “organic solar battery” which requires weatherability in high level.

### EXAMPLES

The present invention will be described below by way of Examples and Comparative Examples, and these Examples are merely for illustrative purposes and are not meant to be limiting on the present invention.

### Synthesis of Acrylic Polyol

### Synthetic Example 1

### Acrylic Polyol (Polymer 1)

In a four-necked flask equipped with a stirring blade, a thermometer and a reflux condenser tube, 100 parts by weight of ethyl acetate (manufactured by Wako Pure Chemical Industries, Ltd.) was charged and refluxed at about 80° C. In the flask, 1.0 part by weight of 2,2-azobisisobutyronitrile as a polymerization initiator was added and a mixture of monomers in each amount shown in Table 1 was continuously added dropwise in the flask over 1 hour and 30 minutes. After further heating for 1 hour, a step of the addition of 0.2 part by weight of 2,2-azobisisobutyronitrile and reacting for 1 hour was repeated four times. As a result, a solution of an acrylic polyol having a non-volatile content (solid content) of 50% by weight was obtained.

The composition of the polymerizable monomer component of the acrylic polyol (polymer 1) and physical properties of the obtained polymer 1 are shown in Table 1.

### Synthesis Examples 2 to 14

### Acrylic Polyols (Polymers 2 to 14)

In the same manner as in Synthetic Example 1, except that the molecular weight was controlled by an addition amount of 2,2-azobisisobutyronitrile, and the composition of monomers used in the synthesis of the acrylic polyol in Synthetic Example 1 was changed as shown in Tables 1 and 2, acrylic polyols (polymers 2 to 14) were obtained. Physical properties of the obtained polymers 2 to 14 are shown in Tables 1 and 2.

The polymerizable monomers shown in Tables 1 and 2, and other components are shown below.

Styrene (St): manufactured by Wako Pure Chemical Industries, Ltd.

Methyl methacrylate (MMA): manufactured by Wako Pure Chemical Industries, Ltd.

Butyl acrylate (BA): manufactured by Wako Pure Chemical Industries, Ltd.

Ethyl acrylate (EA): manufactured by Wako Pure Chemical Industries, Ltd.

2-Ethylhexyl acrylate (2EHA): manufactured by Wako Pure Chemical Industries, Ltd.

Cyclohexyl methacrylate (CHMA): manufactured by Wako Pure Chemical Industries, Ltd.

Glycidyl methacrylate (GMA): manufactured by Wako Pure Chemical Industries, Ltd.

Acrylonitrile (AN): manufactured by Wako Pure Chemical Industries, Ltd.

2-Hydroxyethyl methacrylate (HEMA): manufactured by Wako Pure Chemical Industries, Ltd.

2-Hydroxyethyl acrylate (HEA): manufactured by Wako Pure Chemical Industries, Ltd.

2-(2′-hydroxy-5′-methacryloyloxyethylphenyl)-2H-benzotriazole: (RUVA93 (trade name), manufactured by Otsuka Chemical Co., Ltd.)

TABLE 1

| | Synthetic Examples | | | | | | |
|---|---|---|---|---|---|---|---|
| | 1 | 2 | 3 | 4 | 5 | 6 | 7 |
| St | 0 | 2 | 3 | 2 | 2 | 3 | 3 |
| MMA | 4 | 3 | 25 | 30 | 23 | 32 | 22 |
| BA | 80 | 73 | 60 | 57 | 55 | 54 | 56 |
| EA | 0 | 0 | 0 | 0 | 0 | 0 | 0 |
| 2EHA | 0 | 0 | 0 | 0 | 0 | 0 | 0 |
| CHMA | 0 | 0 | 0 | 0 | 0 | 0 | 0 |
| GMA | 10 | 0 | 0 | 0 | 0 | 2 | 2 |
| AN | 10 | 20 | 10 | 10 | 10 | 5 | 15 |
| HEMA | 6 | 2 | 2 | 1 | 10 | 4 | 2 |
| HEA | 0 | 0 | 0 | 0 | 0 | 0 | 0 |
| RUVA93 | 0 | 0 | 0 | 0 | 0 | 0 | 0 |
| Tg (° C.) of | −34 | −24 | −9 | −5 | −5 | −3 | −4 |
| acrylic polyol | | | | | | | |
| Hydroxyl value | 25.9 | 8.6 | 8.6 | 4.3 | 43 | 17.2 | 8.6 |
| (mgKOH/g) | | | | | | | |
| Weight average | 38,000 | 45,000 | 84,000 | 41,000 | 36,000 | 35,000 | 41,000 |
| molecular weight | | | | | | | |
| Polymer | 1 | 2 | 3 | 4 | 5 | 6 | 7 |

TABLE 2

| | Synthetic Examples | | | | | | |
|---|---|---|---|---|---|---|---|
| | 8 | 9 | 10 | 11 | 12 | 13 | 14 |
| St | 10 | 3 | 2 | 0 | 2 | 0 | 0 |
| MMA | 20 | 28 | 8 | 35 | 22 | 14 | 0 |
| BA | 56 | 55 | 53 | 0 | 55 | 0 | 0 |
| EA | 0 | 0 | 0 | 57 | 0 | 0 | 0 |
| 2EHA | 0 | 0 | 0 | 0 | 0 | 40 | 0 |
| CHMA | 0 | 0 | 0 | 0 | 0 | 42 | 0 |
| GMA | 0 | 2 | 0 | 0 | 0 | 2 | 0 |
| AN | 10 | 10 | 35 | 6 | 10 | 0 | 30 |
| HEMA | 4 | 0 | 2 | 2 | 10 | 2 | 70 |
| HEA | 0 | 2 | 0 | 0 | 0 | 0 | 0 |
| RUVA93 | 0 | 0 | 0 | 0 | 1 | 0 | 0 |
| Tg (° C.) of | −4 | −4 | 4 | 22 | −5 | 0 | 0 |
| acrylic polyol | | | | | | | |
| Hydroxyl value | 17.2 | 9.7 | 8.6 | 8.6 | 43 | 8.6 | 301 |
| (mgKOH/g) | | | | | | | |
| Weight average | 15,000 | 46,000 | 43,000 | 42,000 | 35,000 | 36,000 | 32,000 |
| molecular weight | | | | | | | |
| Polymer | 8 | 9 | 10 | 11 | 12 | 13 | 14 |

### <Calculation of Glass Transition Temperature (Tg) of Polymer>

Tgs of the polymers 1 to 14 were calculated by the previously mentioned formula (i) using the glass transition temperatures of homopolymers of the “polymerizable monomers” as a raw material of each polymer.

A document value was used as Tg of each homopolymer of methyl methacrylate and the like.

Hydroxyl values and weight average molecular weights of the polymers 1 to 14 were measured by the above-mentioned methods.

### <Production of Adhesive for Solar Battery Protective Sheets>

Raw materials of adhesives for solar battery protective sheets used in Examples and Comparative Examples are shown below.

(a1) Acrylic Polyol(s)

The acrylic polyols correspond to the polymers 1 to 12 shown in Tables 1 and 2.

(a′1-1) Acrylic Polyol(s)′

The acrylic polyols' correspond to the polymers 13 and 14 shown in Table 1.

(a′1-2) Non-Acrylic Polyol(s) (Polyesterpolyol(s))

The non-acrylic polyol corresponds to the polymer 15 shown in Table 4. The polymer 15 was a polyester polyol obtained from HS 2N-226P (trade name) manufactured by HOKOKU Co., Ltd.: phthalic anhydride, 2,4-dibutyl-1,5-pentanediol.

(a2) Isocyanate Compound

(a2-1) Isocyanate compound 1 (hexamethylene diisocyanate SUMIDULE N3300 (trade name) manufactured by Sumika Bayer Urethane Co., Ltd.: isocyanurate form)

(a2-2) Isocyanate compound 2 (hexamethylene diisocyanate SUMIDULE HT (trade name) manufactured by Sumika Bayer Urethane Co., Ltd.: trimethylolpropane adduct (ethyl acetate-containing product) hexamethylene diisocyanate trimer/ethyl acetate=75/25 (weight ratio))

(a2-3) Isocyanate compound 3 (xylylene diisocyanate monomer: TAKENATE 500 (trade name) manufactured by Mitsui Chemicals, Inc.)

(B) Hydroxyphenyltriazine-Based Ultraviolet Absorber

(b1) Hydroxyphenyltriazine 1 (TINUVIN 479 (trade name)) manufactured by BASF Corp., 2-[4-(octyl-2-methylethanoate)oxy-2-hydroxyphenyl]-4,6-[bis(2,4-dimethylphenyl)]-1,3,5-triazine

(b2) Hydroxyphenyltriazine 2 (TINUVIN 405 (trade name) manufactured by BASF Corp.), reaction product of 2-(2,4-dihydroxyphenyl)-4,6-bis-(2,4-dimethylphenyl)-1,3,5-triazine with (2-ethylhexyl)-glycidic ester

(B′) Non-Hydroxyphenyltriazine-Based Ultraviolet Absorber

(b′3) Benzotriazole-based ultraviolet absorber (TINUVIN 928 (trade name) manufactured by BASF Corp.), 2-(2H-benzotriazol-2-yl)-6-(1-methyl-1-phenylethyl)-4-(1,1,3,3-tetramethylbutyl)phenol-3,3-tetramethylbutyl)phenol

(b′4) Hindered amine-based compound (TINUVIN 123 (trade name) manufactured by BASF Corp.), bis(1-octyloxy-2,2,6,6-tetramethyl-4-piperidyl)decanedioate

(b′5) Hindered phenol-based compound (IRGANOX 1330 (trade name) manufactured by BASF Corp.), 1,3,5-trimethyl-2,4,6-tris(3,5-di-t-butyl-4-hydroxybenzyl)benzene

A urethane resin is obtainable by reacting the acrylic polyol (a1) with the isocyanate compound (a2).

The below-mentioned adhesives for solar battery protective sheets of Examples 1 to 13 and Comparative Examples 1 to 6 were produced by using the above-mentioned components, and performances of the obtained adhesives for solar battery protective sheets were evaluated. Production methods and evaluation methods are shown below.

### Example 1

### Production of Adhesive for Solar Battery Protective Sheets

As shown in Table 3, 90.0 g of the polymer 1 (a1) [180 g of an ethyl acetate solution of the polymer 1 (solid content: 50.0% by weight)], 4.1 g of an isocyanate compound 1 (a2-1), 5.9 g of an isocyanate compound 3 (a2-3), 1.0 g of hydroxyphenyltriazine 1 (b1), 0.2 g of a hindered amine-based compound (b′4), and 0.2 g of a hindered phenol-based compound (b′5) were weighed and then mixed to prepare an adhesive solution. Using this solution thus prepared as an adhesive for solar battery protective sheets, the following tests were carried out.

### <Production of Adhesive-Coated PET Sheet 1 and Film Laminate 2>

First, the adhesive for solar battery protective sheets of Example 1 was applied to a transparent polyethylene terephthalate (PET) sheet (manufactured by Mitsubishi Polyester Film Corporation under the trade name of O300EW36) so that the weight of the solid component becomes 10 g/m², and then dried at 80° C. for 5 minutes to obtain an adhesive-coated PET sheet 1.

Then, a surface-treated transparent polyolefin film (linear low-density polyethylene film manufactured by Futamura Chemical Co., Ltd. under the trade name of LL-XUMN #30) was laid on the adhesive-coated surface of the adhesive-coated PET sheet 1 so that the surface-treated surface is brought into contact with the adhesive-coated surface, and then both films were pressed using a hot roll press under the conditions of a pressing pressure (or closing pressure) of 0.9 MPa and 5 m/min. While pressing, both films were aged at 50° C. for 5 days to obtain a film laminate 2.

### <Evaluation>

The adhesive for solar battery protective sheets was evaluated by the following method. The evaluation results are shown in Table 3.

### 1. Evaluation of Initial Adhesion to Film

Under a room temperature environment, the adhesive-coated sheet 1 was cut out into pieces of 15 mm in width, and a surface-treated surface of a surface-treated transparent polyolefin film (linear low-density polyethylene film, manufactured by Futamura Chemical Co., Ltd. under the trade name of LL-XUMN #30) was laid on the adhesive-coated surface of the adhesive-coated sheet 1, and then both films are laminated to each other by pressing using a 2 kg roller in a single reciprocal motion. Using a tensile strength testing machine (manufactured by ORIENTEC Co., Ltd. under the trade name of TENSILON RTM-250), a 180° peel test was carried out under a room temperature environment at a testing speed of 100 mm/min. The evaluation criteria are as shown below.

A: Peel strength is 0.5 N/15 mm or more

B: Peel strength is 0.1 N/15 mm or more and less than 0.5 N/15 mm

C: Peel strength is less than 0.1 N/15 mm

2. Measurement of Adhesion Property (Adhesive Strength) to Film after Aging

A film laminate 2 was cut into pieces of 15 mm in width, and then a 180° peel test was carried out under a room temperature environment at a testing speed of 100 mm/min, using a tensile strength testing machine (manufactured by ORIENTEC Co., Ltd. under the trade name of TENSILON RTM-250). The evaluation criteria are as shown below

A: Peel strength is 10 N/15 mm or more

B: Peel strength is 6 N/15 mm or more and less than 10 N/15 mm

C: Peel strength is 1 N/15 mm or more and less than 6 N/15 mm

### 3. Evaluation of Hydrolysis Resistance

The evaluation was carried out by an accelerated evaluation method using pressurized steam. A film laminate 2 was cut into pieces of 15 mm in width, left to stand under a pressurizing environment at 121° C. under 0.1 MPa for 100 hours using a high-pressure cooker (manufactured by Yamato Scientific Co., Ltd. under the trade name of Autoclave SP300), and then aged under a room temperature environment for one day. Lifting and peeling of the polyolefin film and PET film of the sample were visually observed. The evaluation criteria are as follows.

A: Neither lifting nor peeling of film occurred after being left to stand for 100 hours.

C: Lifting or peeling of film occurred within 100 hours.

### 4. Evaluation of Yellowing by UV Irradiation

A film laminate 2 was mounted to a UV irradiation tester (EYE SUPER UV TESTER SUVW151 (trade name), manufactured by Iwasaki Electric Co., Ltd.) so that the side of a polyolefin film becomes a surface to be irradiated, and then irradiated under the conditions of an illuminance of 1,000 W/m² at 60° C. and 50% RH for 30 hours. Using a color difference meter, a color difference (Δb) was measured before and after irradiation and then yellowness was evaluated. Evaluation criteria are as follows.

A: Δb is less than 15

B: Δb is 15 or more and less than 27

C: Δb is 27 or more

### Examples 2 to 13 and Comparative Examples 1 to 6

In the same manner as in Example 1, adhesives for solar battery protective sheets of Examples 2 to 13 and Comparative Examples 1 to 6 were produced according to the compositions shown in Tables 3 and 4, and then evaluated.

TABLE 3

| | | Examples | | | | | | | | | |
|---|---|---|---|---|---|---|---|---|---|---|---|
| | | 1 | 2 | 3 | 4 | 5 | 6 | 7 | 8 | 9 | 10 |
| (a1) | Polymer 1 | 90 | | | | | | | | | |
| | Polymer 2 | | 95.1 | | | | | | | | |
| | Polymer 3 | | | 92.8 | 90.2 | | | | | | |
| | Polymer 4 | | | | | 97.6 | | | | | |
| | Polymer 5 | | | | | | 88.9 | | | | |
| | Polymer 6 | | | | | | | 95.1 | | | |
| | Polymer 7 | | | | | | | | 96.3 | | |
| | Polymer 8 | | | | | | | | | 95.1 | 93.2 |
| | Polymer 9 | | | | | | | | | | |
| | Polymer 10 | | | | | | | | | | |
| | Polymer 11 | | | | | | | | | | |
| | Polymer 12 | | | | | | | | | | |
| (a1′-1) | Polymer 13 | | | | | | | | | | |
| | Polymer 14 | | | | | | | | | | |
| (a1′-2) | Polymer 15 | | | | | | | | | | |
| (a2) | (a2-1) | 4.1 | 4.9 | | 9.8 | 2.4 | 7.4 | 4.9 | 4.1 | | 6.8 |
| | (a2-2) | | | 5.9 | | | | | | | |
| | (32-3) | 5.9 | | 1.9 | | | 5.1 | | 1.8 | 4.9 | |
| (B) | (b1) | 1 | 2 | 1 | 3 | 1 | 2 | 1 | 2 | 1 | |
| | (b2) | | | | | | | | | | 3 |
| (B′) | (b′3) | | | | | | | | | | |
| | (b′4) | 0.2 | 0.2 | 0.2 | 0.2 | 0.2 | 0.2 | 0.2 | 0.2 | 0.2 | 0.2 |
| | (b′5) | 0.2 | 0.2 | 0.2 | 0.2 | 0.2 | 0.2 | 0.2 | 0.2 | 0.2 | 0.2 |

| | | | | | | | | | | |
|---|---|---|---|---|---|---|---|---|---|---|
| Initial adhesion | ⊚ | ⊚ | ⊚ | ⊚ | ⊚ | ⊚ | ⊚ | ⊚ | ⊚ | ⊚ |
| to film | | | | | | | | | | |
| Peel strength | ◯ | ⊚ | ⊚ | ⊚ | ⊚ | ◯ | ◯ | ⊚ | ⊚ | ⊚ |
| (N/15 mm) | | | | | | | | | | |
| Hydrolysis | ⊚ | ⊚ | ⊚ | ⊚ | ⊚ | ⊚ | ⊚ | ⊚ | ⊚ | ⊚ |
| resistance | | | | | | | | | | |
| Δb after UV | ◯ | ◯ | ◯ | ⊚ | ◯ | ⊚ | ⊚ | ◯ | ◯ | ◯ |
| irradiation for | | | | | | | | | | |
| 30 hours | | | | | | | | | | |

TABLE 4

| | | Examples | | | Comparative Examples | | | | | |
|---|---|---|---|---|---|---|---|---|---|---|
| | | 11 | 12 | 13 | 1 | 2 | 3 | 4 | 5 | 6 |
| | Polymer 1 | | | | | | | | | |
| | Polymer 2 | | | | | | | | | |
| (a1) | Polymer 3 | | | | | | | | | |
| | Polymer 4 | | | | | | | | | |
| | Polymer 5 | | | | | 86.6 | 88.9 | | | |
| | Polymer 6 | | | | | | | | | |
| | Polymer 7 | | | | | | | | | |
| | Polymer 8 | | | | | | | | | |
| | Polymer 9 | 90.2 | | | | | | | | |
| | Polymer 10 | | 95.8 | | | | | | | |
| | Polymer 11 | | | 95.1 | | | | | | |
| | Polymer 12 | | | | | | | 88.9 | | |
| (a1′-1) | Polymer 13 | | | | 93.2 | | | | | |
| | Polymer 14 | | | | | | | | 95.1 | |
| (a1′-2) | Polymer 15 | | | | | | | | | 86.5 |
| (a2) | (a2-1) | 9.8 | 4.4 | 4.9 | 6.8 | 13.4 | 7.4 | 7.4 | 4.9 | 13.5 |
| | (a2-2) | | | | | | | | | |
| | (a2-3) | | 1.4 | | | | 5.1 | 5.1 | | |
| (B) | (b1) | 1 | 3 | 1 | 1 | | | | 3 | 1 |
| | (b2) | | | | | | | | | |
| (B′) | (b′3) | | | | | | 3 | | | |
| | (b′4) | 0.2 | 0.2 | 0.2 | 0.2 | | 0.2 | 0.2 | 0.2 | 0.2 |
| | (b′5) | 0.2 | 0.2 | 0.2 | 0.2 | | 0.2 | 0.2 | 0.2 | 0.2 |

| | | | | | | | | | |
|---|---|---|---|---|---|---|---|---|---|
| Initial adhesion | ⊚ | ◯ | ◯ | ◯ | ⊚ | ⊚ | ⊚ | X | ⊚ |
| to film | | | | | | | | | |
| Peel strength | ⊚ | ⊚ | ◯ | X | ◯ | ◯ | ◯ | ◯ | ⊚ |
| (N/15 mm) | | | | | | | | | |
| Hydrolysis | ⊚ | ⊚ | ⊚ | ⊚ | ⊚ | ⊚ | ⊚ | X | X |
| resistance | | | | | | | | | |
| Δb after UV | ◯ | ◯ | ◯ | ⊚ | X | X | X | ◯ | X |
| irradiation for | | | | | | | | | |
| 30 hours | | | | | | | | | |

As shown in Tables 1 to 4, since the adhesives for solar battery protective sheets of Examples 1 to 13 contain a urethane resin obtainable by the reaction of an acrylic polyol (a1) with an isocyanate compound (a2), and the acrylic polyol (a1) includes acrylonitrile and a (meth)acrylic ester, the obtained adhesives were excellent in initial adhesion to a film, adhesive strength (peel strength) after aging, and were also excellent in hydrolysis resistance and weatherability and had satisfactory total balance. Therefore, the adhesives of the Examples are suited for the use as an adhesive for solar battery protective sheets.

Particularly, the adhesives for solar battery protective sheets of Examples 4, 6 and 7 were significantly excellent in weatherability, and were also excellent in initial adhesion to a film, adhesive (peel) strength to a film after aging, and hydrolysis resistance, and thus the adhesives are suited for the use as an adhesive for protective sheets of an organic (dye-sensitized) solar battery.

To the contrary, the adhesive of Comparative Example 1 was inferior in peel strength since the polymerizable monomers contain no acrylonitrile.

The adhesives of Comparative Examples 2 to 4 were drastically inferior in weatherability (light resistance) since the polymerizable monomers contain no hydroxyphenyltriazine-based compound.

The adhesive of Comparative Example 5 was inferior in initial adhesion to a film and hydrolysis resistance since the polymerizable monomers comprise no (meth)acrylic acid ester while the adhesive comprises a hydroxyphenyltriazine-based compound.

The adhesive of Comparative Example 6 exhibited poor hydrolysis resistance and weatherability since the adhesive does not comprise a resin obtainable by mixing an acrylic polyol with an isocyanate compound, but comprises a resin obtainable by mixing a polyester polyol with an isocyanate compound.

These results revealed that a urethane adhesive including a urethane resin obtainable by the reaction of an acrylic polyol (a1) with an isocyanate compound (a2), and a hydroxyphenyltriazine-based compound, polymerizable monomers as raw materials of the acrylic polyol (a1) containing both acrylonitrile and a (meth)acrylic acid ester, is excellent for the production of a solar battery protective sheet.

### INDUSTRIAL APPLICABILITY

The present invention provides an adhesive for solar battery protective sheets. The adhesive for solar battery protective sheets according to the present invention is excellent in initial adhesion to a film, adhesion property after aging, hydrolysis resistance and long-term weatherability, and is suited for the production of a solar battery protective sheet and a solar battery module, and also it is particularly effective for the production of an organic solar battery.

### DESCRIPTION OF REFERENCE NUMERALS

1: Solar battery module, 10: Back sheet, 11: Film, 11a: Deposited thin film, 12: Film, 13: Adhesive layer

20: Sealing material (EVA), 30: Solar battery cell

40: Glass plate, 50: Spacer

1. An adhesive for solar battery protective sheets, comprising a urethane resin reaction product of an acrylic polyol with an isocyanate compound; and a hydroxyphenyltriazine based compound,
wherein the acrylic polyol is the polymerization product of polymerizable monomers,
the polymerizable monomers comprise a first monomer having a hydroxyl group and other monomers different from the first monomer, and
the other monomers comprise acrylonitrile and (meth)acrylic ester(s).

2. The adhesive for solar battery protective sheets according to claim 1, wherein the acrylic polyol has a glass transition temperature of −40° C. to 20° C.

3. The adhesive for solar battery protective sheets according to claim 1, wherein the content of the acrylonitrile is 1 to 40 parts by weight based on 100 parts by weight of the polymerizable monomers.

4. A solar battery protective sheet comprising the adhesive for solar battery protective sheets according to claim 1.

5. A solar battery module comprising the solar battery protective sheet according to claim 4.

6. The adhesive for solar battery protective sheets according to claim 1, wherein the first monomer having a hydroxyl group comprises hydroxyalkyl (meth)acrylate.

7. The adhesive for solar battery protective sheets according to claim 1, wherein the first monomer having a hydroxyl group comprises hydroxyalkyl (meth)acrylate and a monomer having a hydroxyl group, other than the hydroxyalkyl (meth)acrylate.

8. The adhesive for solar battery protective sheets according to claim 1, wherein the first monomer having a hydroxyl group comprises at least one of 2-hydroxyethyl (meth)acrylate, 2-hydroxypropyl (meth)acrylate, 3-hydroxypropyl (meth)acrylate and 4-hydroxybutyl acrylate.

9. The adhesive for solar battery protective sheets according to claim 1, wherein the first monomer having a hydroxyl group comprises hydroxyalkyl (meth)acrylate and at least one of polyethylene glycol mono(meth)acrylate and polypropylene glycol mono(meth)acrylate.

10. The adhesive for solar battery protective sheets according to claim 1, wherein the other monomers different from the first monomer are radical polymerizable monomers having an ethylenic double bond.

11. The adhesive for solar battery protective sheets according to claim 1, wherein the (meth)acrylic ester(s) have an ester bond and are the condensation reaction product of (meth)acrylic acid and a monoalcohol.

12. The adhesive for solar battery protective sheets according to claim 1, wherein the (meth)acrylic ester(s) are selected from at least one of methyl (meth)acrylate, ethyl (meth)acrylate, butyl (meth)acrylate, cyclohexyl (meth)acrylate, 2-ethylhexyl (meth)acrylate, dicyclopentanyl (meth)acrylate, glycidyl (meth)acrylate, isobornyl (meth)acrylate.

13. The adhesive for solar battery protective sheets according to claim 1, wherein the (meth)acrylic ester(s) are butyl acrylate and methyl methacrylate.

14. The adhesive for solar battery protective sheets according to claim 1, wherein the content of the (meth)acrylic ester(s) is 50 to 95 parts by weight based on 100 parts by weight of the polymerizable monomers.

15. The adhesive for solar battery protective sheets according to claim 1, wherein the other monomers different from the first monomer further include at least one of (meth)acrylic acid, styrene and vinyltoluene.

16. The adhesive for solar battery protective sheets according to claim 1, wherein the acrylic polyol has a hydroxyl value of 0.5 to 45 mgKOH/g.

17. The adhesive for solar battery protective sheets according to claim 1, wherein the isocyanate compound consists of an aliphatic isocyanate.

18. Cured reaction products of the adhesive for solar battery protective sheets according to claim 1.

19. A raw material comprising an acrylic polyol for producing the adhesive according to claim 1,
wherein the acrylic polyol is obtained by polymerizing polymerizable monomers,
the polymerizable monomers comprise a first monomer having a hydroxyl group and other monomers different from the first monomer, and
the other monomers comprise acrylonitrile and (meth)acrylic ester(s).
